(19) United States
(12) Patent Application Publication
(10) Pub. No.: US 2023/0157071 A1
(43) Pub. Date: May 18, 2023

(54) DISPLAY PANEL AND METHOD OF MANUFACTURING THE SAME

(71) Applicant: Samsung Display Co., Ltd., Yongin-si (KR)

(72) Inventors: YOUNGKUK KIM, Seoul (KR); SWAE-HYUN KIM, Asan-si (KR); YOUHAN MOON, Bucheon-si (KR)

(21) Appl. No.: 17/902,540

(22) Filed: Sep. 2, 2022

(30) Foreign Application Priority Data
Nov. 18, 2021 (KR) 10-2021-0159016

(51) Int. Cl. H01L 27/32; H01L 29/786; H01L 29/66

(52) U.S. Cl. CPC H01L 27/3262; H01L 27/3265; H01L 29/7869; H01L 29/66742; H01L 2227/323

(57) ABSTRACT

A display panel includes a light emitting element and a pixel circuit electrically connected to the light emitting element. The pixel circuit includes a transistor. The transistor includes a first gate, an oxide semiconductor member overlapping the first gate, and a second gate overlaps the oxide semiconductor member. The oxide semiconductor member is disposed between the first gate and the second gate and includes a first semiconductor layer and a second semiconductor layer. The second semiconductor layer is disposed between the first semiconductor layer and the second gate in a thickness direction of the oxide semiconductor member. An atomic percent of oxygen of the first semiconductor layer is lower than an atomic percent of oxygen of the second semiconductor layer.

This U.S. non-provisional patent application claims priority under 35 U.S.C. § 119 to Korean Patent Application No. 10-2021-0159016 filed on Nov. 18, 2021; the Korean Patent Application is incorporated by reference.

### BACKGROUND

### 1. Field

The technical field is related to a display panel and a method of manufacturing the display panel.

### 2. Description of the Related Art

A display device typically includes a display panel for displaying images in response to input signals. The display panel may include a light emitting element and a pixel circuit. The pixel circuit may include a transistor for controlling transmission of an electrical signal to the light emitting element.

### SUMMARY

Embodiments may be related to a display panel including an oxide transistor with satisfactory durability.

Embodiments may be related to a method of manufacturing the display panel including the oxide transistor.

Embodiments may be related to a display panel including a light emitting element and a pixel circuit electrically connected to the light emitting element. The pixel circuit includes a first transistor. The first transistor includes a bottom gate, an oxide semiconductor pattern disposed on the bottom gate, a top gate disposed on the oxide semiconductor pattern, a first insulating layer disposed between the bottom gate and the oxide semiconductor pattern, and a second insulating layer disposed between the oxide semiconductor pattern and the top gate.

The oxide semiconductor pattern includes a first area and a second area disposed on the first area in a thickness direction of the oxide semiconductor pattern. The first area has an atomic percent (%) of oxygen, which is lower than an atomic percent (%) of oxygen of the second area. The first area has a thickness from about 100 angstroms to about 150 angstroms, and the second area has a thickness from about 100 angstroms to about 150 angstroms.

The oxide semiconductor pattern further includes a boundary area disposed between the first area and the second area, having an atomic percent (%) of oxygen, which is higher than the atomic percent (%) of oxygen of the first area, and having the atomic percent (%) of oxygen, which is lower than the atomic percent (%) of oxygen of the second area, and the boundary area has a thickness smaller than a thickness of the first area and a thickness of the second area.

The atomic percent (%) of oxygen of the first area is lower than the atomic percent (%) of oxygen of the second area by about 2 atomic percent (%) oxygen.

The oxide semiconductor pattern includes an indium gallium zinc oxide, and the atomic percent (%) of oxygen of the first area is in a range from about 40 atomic percent (%) of oxygen to about 60 atomic percent (%) of oxygen with respect to the indium gallium zinc oxide.

The pixel circuit further includes a capacitor. The capacitor includes a first electrode disposed on the same layer as a layer on which the oxide semiconductor pattern is disposed and including the same transparent conductive oxide as the oxide semiconductor pattern, and a second electrode disposed under the first electrode.

The first insulating layer extends to be disposed between the first electrode and the second electrode.

The first insulating layer includes a silicon oxide layer and a silicon nitride layer disposed on the silicon oxide layer, and the first insulating layer has a thickness from about 1000 angstroms to about 1500 angstroms.

The first insulating layer has a thickness smaller than a thickness of the second insulating layer.

The pixel circuit further includes a second transistor and an upper electrode, the second transistor includes a silicon semiconductor pattern and a gate disposed on the silicon semiconductor pattern. The upper electrode is disposed above the gate. The upper electrode is disposed on the same layer as a layer on which the oxide semiconductor pattern is disposed and includes the same transparent conductive oxide as the oxide semiconductor pattern.

The first insulating layer extends to be disposed between the gate and the upper electrode.

The bottom gate and the gate include the same material.

The display panel further includes a third insulating layer covering the top gate and a connection electrode disposed on the third insulating layer and electrically connecting the top gate and the bottom gate.

The connection electrode is connected to the top gate via a first contact hole defined through the third insulating layer and is connected to the bottom gate via a second contact hole defined through the first insulating layer, the second insulating layer, and the third insulating layer.

The second area includes a channel area that overlaps the top gate, a drain area that does not overlap the top gate, and a source area that does not overlap the top gate when viewed in a plane.

Embodiments may be related to a method of manufacturing a display panel. The method includes forming a bottom gate, forming a first insulating layer on the bottom gate of a first transistor, forming an oxide semiconductor pattern of the first transistor on the first insulating layer, forming a second insulating layer on the oxide semiconductor pattern, and forming a top gate of the first transistor on the second insulating layer. The forming of the oxide semiconductor pattern includes performing a first sputtering to form a first oxide semiconductor layer, performing a second sputtering to form a second oxide semiconductor layer on the first oxide semiconductor layer, and patterning the first oxide semiconductor layer and the second oxide semiconductor layer. The first sputtering is performed at a power lower than a power at which the second sputtering is performed or an oxygen partial pressure in a reactive gas used in the first sputtering is lower than an oxygen partial pressure in a reactive gas used in the second sputtering.

The method further includes forming a connection electrode that connects the top gate and the bottom gate.

The oxygen partial pressure in the reactive gas of the first sputtering is in a range from about 10% to about 60%.

The method further includes forming a silicon semiconductor pattern of a second transistor before the forming of the bottom gate. A gate of the second transistor is formed through a same process as the forming of the bottom gate, and the gate of the second transistor is spaced apart from the bottom gate and overlaps the silicon semiconductor pattern.

The method further includes forming an upper electrode through the same process as the forming of the oxide semiconductor pattern, and the upper electrode is spaced apart from the oxide semiconductor pattern and overlaps the gate of the second transistor.

An embodiment may be related to a display panel. The display panel may include a light emitting element and a pixel circuit electrically connected to the light emitting element. The pixel circuit may include a first transistor. The first transistor may include a first gate, an oxide semiconductor member overlapping the first gate, a second gate overlapping the oxide semiconductor member, a first insulating layer disposed between the first gate and the oxide semiconductor member, and a second insulating layer disposed between the oxide semiconductor member and the second gate. The oxide semiconductor member may be disposed between the first gate and the second gate, may include a first semiconductor layer, and may include a second semiconductor layer disposed between the first semiconductor layer and the second gate in a thickness direction of the oxide semiconductor member. An atomic percent of oxygen of the first semiconductor layer may be lower than an atomic percent of oxygen of the second semiconductor layer.

A thickness of the first semiconductor layer may be in a range of 100 angstroms to 150 angstroms. A thickness of the second semiconductor layer may be in a range of 100 angstroms to 150 angstroms.

The oxide semiconductor member may include a boundary semiconductor layer disposed between the first semiconductor layer and the second semiconductor layer. An atomic percent of oxygen of the boundary semiconductor layer may be higher than the atomic percent of oxygen of the first semiconductor layer and may be lower than the atomic percent of oxygen of the second semiconductor layer. A maximum thickness of the boundary semiconductor layer may be less than each of a maximum thickness of the first semiconductor layer and a maximum thickness of the second semiconductor layer in the thickness direction of the oxide semiconductor member.

The atomic percent of oxygen of the first semiconductor layer may be lower than the atomic percent of oxygen of the second semiconductor layer by at least 2 atomic percent.

The oxide semiconductor member may include an indium gallium zinc oxide. The atomic percent of oxygen of the first semiconductor layer may be in a range from 40 atomic percent to 60 atomic percent.

The pixel circuit may include a capacitor. The capacitor may include a first electrode and a second electrode. The first electrode may be disposed on the first insulating layer and may include a same transparent conductive oxide as the oxide semiconductor member. The first electrode and the second electrode may overlap each other.

The first insulating layer may be partially disposed between the first electrode and the second electrode.

The first insulating layer may include a silicon oxide layer and a silicon nitride layer disposed on the silicon oxide layer. A thickness of the first insulating layer may be in a range from 1000 angstroms to 1500 angstroms.

A maximum thickness of the first insulating layer may be less than a maximum thickness of the second insulating layer in the thickness direction of the oxide semiconductor member.

The pixel circuit may include a second transistor and an overlapping electrode. The second transistor may include a silicon semiconductor member and a gate electrode. The gate electrode may overlap the silicon semiconductor member and may be disposed between the overlapping electrode and the silicon semiconductor member. The overlapping electrode may overlap the gate electrode, may be disposed on the first insulating layer, and may include a same transparent conductive oxide as the oxide semiconductor member.

The first insulating layer may be partially disposed between the gate electrode and the overlapping electrode.

The first gate of the first transistor and the gate electrode of the second transistor may include a same material.

The display panel may include a third insulating layer and a connection electrode. The third insulating layer may cover the second gate. The connection electrode may be disposed on the third insulating layer and may electrically connect the second gate and the first gate.

The connection electrode may be connected to the second gate via a first contact hole through the third insulating layer and may be connected to the first gate via a second contact hole through the first insulating layer, the second insulating layer, and the third insulating layer.

The second semiconductor layer may include a channel, a drain, and a source. The channel may be overlapped by the second gate and may be positioned between the drain and the source.

An embodiment may be related to a method of manufacturing a display panel. The method may include the following steps: forming a first gate of a first transistor: forming a first insulating layer on the first gate; forming an oxide semiconductor member of the first transistor on the first insulating layer; forming a second insulating layer on the oxide semiconductor member; and forming a second gate of the first transistor on the second insulating layer. The forming of the oxide semiconductor member may include the following steps: forming a first semiconductor layer by performing at least a first sputtering process; and forming a second semiconductor layer on the first semiconductor layer by performing at least a second sputtering process. The first sputtering process and the second sputtering process may be performed according to at least one of a first condition and a second condition. A power for performing the first sputtering process may be lower than a power for performing the second sputtering process according to the first condition. An oxygen partial pressure in a reactive gas used in the first sputtering process may be lower than an oxygen partial pressure in a reactive gas used in the second sputtering process according to the second condition. The second semiconductor layer may be positioned between the first semiconductor layer and the second gate in the display panel.

The method may include forming a connection electrode that electrically connects the second gate and the first gate.

The oxygen partial pressure in the reactive gas of the first sputtering process may be in a range from 10% to 60%.

The method may include forming a silicon semiconductor member of a second transistor before the forming of the first gate. A gate of the second transistor may be formed during the forming of the first gate. The gate of the second transistor may be spaced from the first gate and may overlap the silicon semiconductor member.

The method may include forming an overlapping electrode during the forming of the oxide semiconductor member. The overlapping electrode may be spaced from the oxide semiconductor member and may overlap the gate of the second transistor.

According to embodiments, a threshold voltage variation by positive bias temperature stress (PBTS) may be reduced or minimized.

According to embodiments, a structure of a display panel including a silicon transistor and an oxide transistor may be substantially simple. The number of the conductive layers in the display panel may be minimized. The number of masks used in the process of manufacturing is the display panel may be minimized.

### BRIEF DESCRIPTION OF THE DRAWINGS

FIG. 1 is a plan view of a display panel according to an embodiment.

FIG. 2 is a cross-sectional view of a display panel according to an embodiment.

FIG. 3A is a block diagram of a display device according to an embodiment.

FIG. 3B is an equivalent circuit diagram of a pixel according to an embodiment.

FIG. 3C is a waveform diagram of driving signals used to drive a pixel according to an embodiment.

FIG. 4 is a cross-sectional view of a display panel according to an embodiment.

FIG. 5A is a cross-sectional view of an oxide transistor according to an embodiment.

FIG. 5B is a cross-sectional view of an oxide transistor according to an embodiment.

FIG. 6 is a graph of a variation of a threshold voltage as a function of an electric power in a sputtering process.

FIG. 7 is a graph of a variation of a threshold voltage as a function of an oxygen partial pressure in a sputtering process.

### DETAILED DESCRIPTION

Examples of embodiments are described with reference to the accompanying drawings.

Like numerals may refer to like elements. In the drawings, dimensions may be exaggerated for clarity.

It will be understood that, although the terms “first,” “second,” etc. may be used herein to describe various elements, these elements should not be limited by these terms. These terms may be used to distinguish one element from another element. A first element may be termed a second element without departing from the teachings of one or more embodiments. The description of an element as a “first” element may not require or imply the presence of a second element or other elements. The terms “first,” “second,” etc. may be used to differentiate different categories or sets of elements. For conciseness, the terms “first,” “second,” etc. may represent “first-category (or first-set),” “second-category (or second-set),” etc., respectively.

The singular forms, “a”, “an,” and “the” may indicate the plural forms as well, unless the context clearly indicates otherwise.

The terms “include” and/or “including” may specify the presence of stated features and/or elements, and may not preclude the presence or addition of one or more other features and/or elements.

The term “on” may mean “directly on” or “indirectly on.” The term “connect” may mean “directly connect” or “indirectly connect.” The term “connect” may mean “mechanically connect” and/or “electrically connect.” The term “connected” may mean “electrically connected” or “electrically connected through no intervening transistor.” The term “insulate” may mean “electrically insulate” or “electrically isolate.” The term “conductive” may mean “electrically conductive.” The term “drive” may mean “operate” or “control.” The term “include” may mean “be made of.” The term “adjacent” may mean “immediately adjacent.” The expression that an element extends in a particular direction may mean that the element extends lengthwise in the particular direction and/or that the lengthwise direction of the element is in the particular direction. The term “pattern” may mean “member.” The term “defined” may mean “formed” or “provided.” The expression that a space or opening overlaps an object may mean that (the position of) the space or opening overlaps with (the position of) the object. The term “overlap” may be equivalent to “be overlapped by.” The expression that a first element overlaps with a second element in a plan view may mean that the first element overlaps the second element in direction perpendicular to a substrate. The symbol “%” may mean “at. %.” The term “area” may mean “layer” or “portion.”

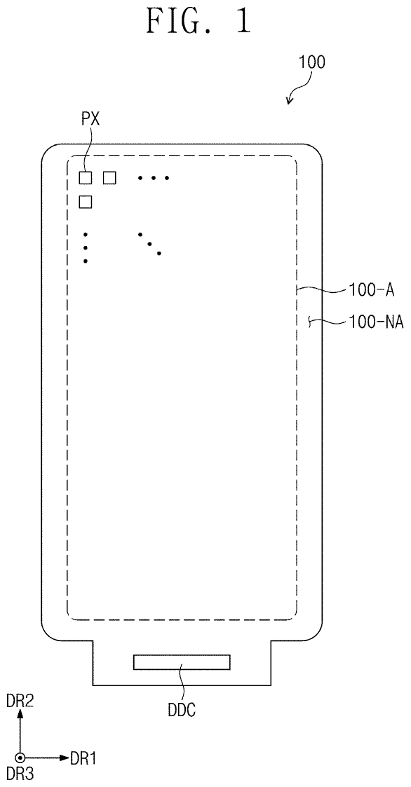

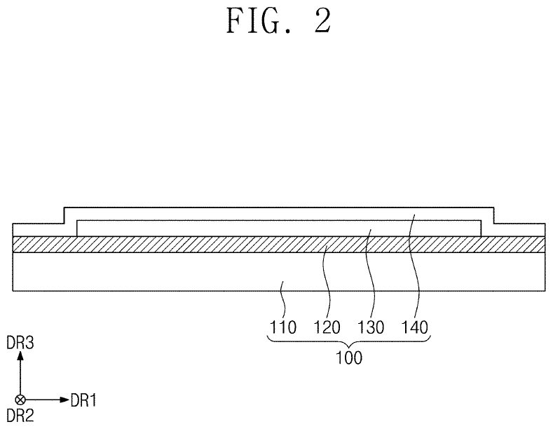

FIG. 1 is a plan view of a display panel 100 according to an embodiment, and FIG. 2 is a cross-sectional view of the display panel 100 according to an embodiment.

Referring to FIG. 1, the display panel 100 may include a display area 100-A and a non-display area 100-NA. The non-display area 100-NA may be defined adjacent to the display area 100-A and may surround at least a portion of the display area 100-A. A pixel PX may be disposed in the display area 100-A and may not be disposed in the non-display area 100-NA. A data driving circuit DDC may be disposed at one side portion of the non-display area 100-NA.

The display area 100-A may include a surface defined by a first direction DR1 and a second direction DR2. A third direction DR3 may be perpendicular to the surface of the display area 100-A and may indicate a thickness direction of the display panel 100. Front (or upper) and rear (or lower) surfaces of each member of the display panel 100 may be defined with reference to the third direction DR3.

The display panel 100 may be a light emitting type display panel. For example, the display panel 100 may be an organic light emitting display panel, an inorganic light emitting display panel, a micro-LED display panel, or a nano-LED display panel. The display panel 100 may be flexible. Although not shown in figures, the display panel 100 may be folded with respect to at least one folding axis. The display area 100-A may be folded.

Referring to FIG. 2, the display panel 100 may include a base layer 110, a circuit layer 120, a light emitting element layer 130, and an encapsulation layer 140. One or more functional layers may be disposed between two of the base layer 110, the circuit layer 120, the light emitting element layer 130, and the encapsulation layer 140.

The base layer 110 may provide a base surface on which the circuit layer 120 is disposed. The base layer 110 may be a flexible substrate that is bendable, foldable, and/or rollable. The base layer 110 may be/include a glass substrate, a metal substrate, and/or a polymer substrate. The base layer 110 may be/include an inorganic layer, an organic layer, and/or a composite material layer.

The base layer 110 may have a multi-layer structure. For instance, the base layer 110 may include a first synthetic resin layer, an inorganic layer having a single-layer or multi-layer structure, and a second synthetic resin layer disposed on the inorganic layer having a single-layer or multi-layer structure. Each of the first and second synthetic resin layers may include a polyimide-based resin.

The circuit layer 120 may be disposed on the base layer 110. The circuit layer 120 may include an insulating layer, a semiconductor pattern, a conductive pattern, and a signal line.

The light emitting element layer 130 may be disposed on the circuit layer 120. The light emitting element layer 130 may include a light emitting element. The light emitting element may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from moisture, oxygen, and a foreign substance such as dust particles. The encapsulation layer 140 may include at least one inorganic layer. The encapsulation layer 140 may include a stack structure in which an inorganic layer, an organic layer, and an inorganic layer are sequentially stacked.

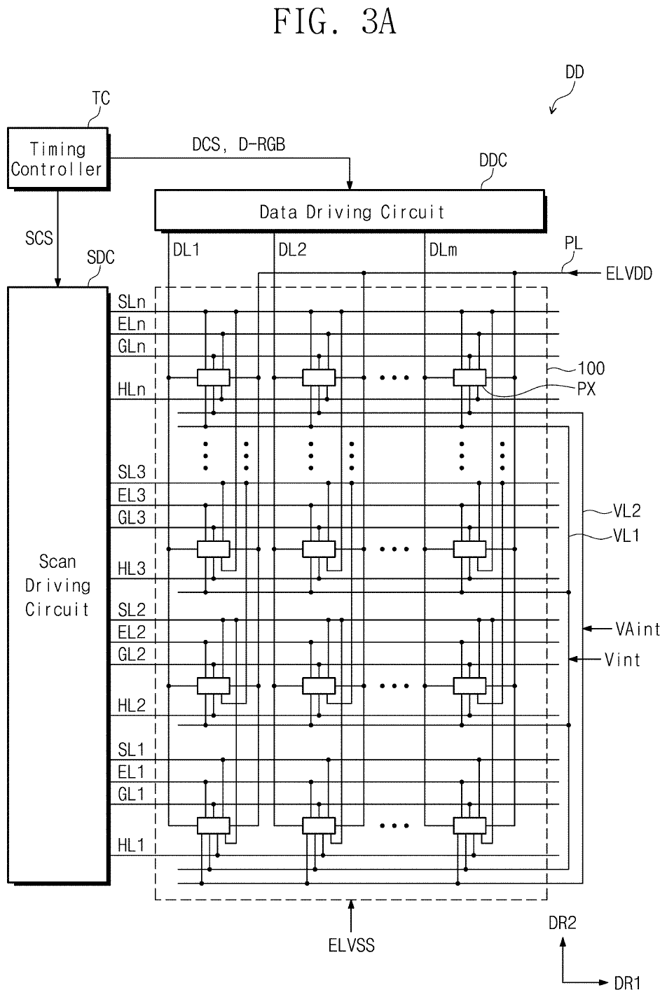

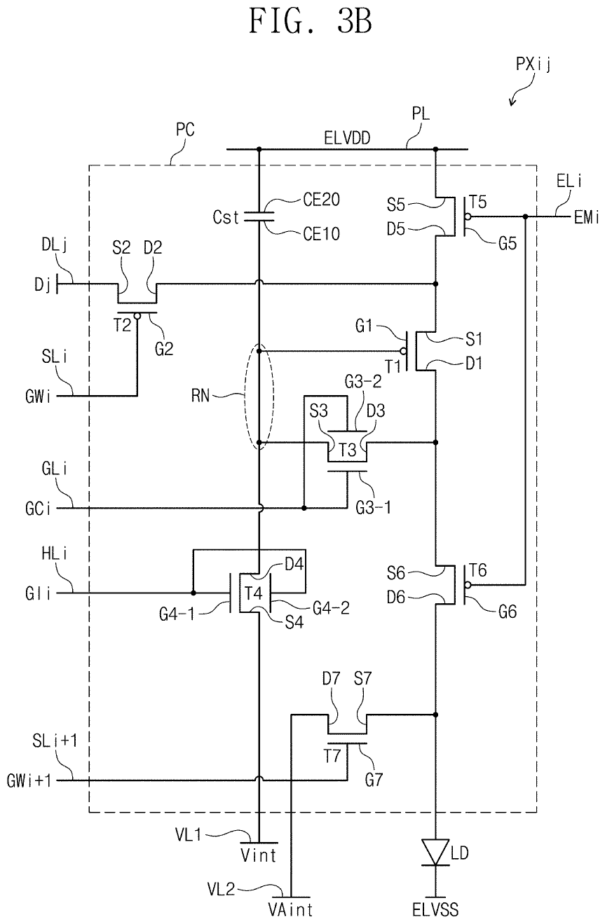

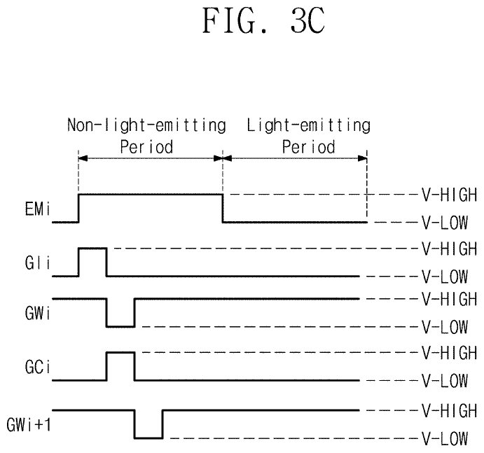

FIG. 3A is a block diagram of a display device DD according to an embodiment. FIG. 3B is an equivalent circuit diagram of a pixel PXij according to an embodiment. FIG. 3C is a waveform diagram of driving signals used to drive a pixel PX according to an embodiment.

The display device DD may include a timing controller TC, a scan driving circuit SDC, the data driving circuit DDC, and the display panel 100. At least one of the timing controller TC, the scan driving circuit SDC, and the data driving circuit DDC may be provided in the form of a driving chip or may be directly formed in the display panel 100.

The timing controller TC may receive input image signals, may convert a data format of the input image signals to a data format appropriate to an interface between the timing controller TC and the scan driving circuit SDC, and may generate image data D-RGB. The timing controller TC may output the image data D-RGB and various control signals DCS and SCS.

The scan driving circuit SDC may receive a scan control signal SCS from the timing controller TC. The scan control signal SCS may include a vertical start signal to start an operation of the scan driving circuit SDC and a clock signal to determine an output timing of signals. The scan driving circuit SDC may generate a plurality of scan signals and may sequentially output the scan signals to corresponding signal lines SL1, SL2, SL3 to SLn; GL1, GL2, GL3 to GLn; and HL1, HL2, HL3 to HLn. In addition, the scan driving circuit SDC may generate a plurality of light emitting control signals in response to the scan control signal SCS and may output the light emitting control signals to corresponding light emitting lines ELL EL2, EL3 to ELn.

The data driving circuit DDC may receive a data control signal DCS and the image data D-RGB from the timing controller TC. The data driving circuit DDC may convert the image data D-RGB to data signals and may output the data signals to a plurality of data lines DL1, DL2 to DLm described later. The data signals may be analog voltages corresponding to grayscale values of the image data D-RGB.

Groups of signal lines may include a first group of scan lines SL1 to SLn, a second group of scan lines GL1 to GLn, a third group of scan lines HL1 to HLn, the light emitting lines EL1 to ELn, the data lines DL1 to DLm, a first voltage line PL, a second voltage line VL1, and a third voltage line VL2. The first group of scan lines SL1 to SLn, the second group of scan lines GL1 to GLn, the third group of scan lines HL1 to HLn, and the light emitting lines EL1 to ELn may extend in the first direction DR1 and may be arranged in the second direction DR2 different from the first direction DR1. The data lines DL1 to DLm may be insulated from the first group of scan lines SL1 to SLn, the second group of scan lines GL1 to GLn, the third group of scan lines HL1 to HLn, and the light emitting lines EL1 to ELn and may cross the first group of scan lines SL1 to SLn, the second group of scan lines GL1 to GLn, the third group of scan lines HL1 to HLn, and the light emitting lines EL1 to ELn.

Each of the first voltage line PL, the second voltage line VL1, and the third voltage line VL2 may include at least one of a section extending in the first direction DR1 and a section extending in the second direction DR2. The structures and the shapes of the first voltage line PL, the second voltage line VL1, and the third voltage line VL2 may be independently designed.

Each of the pixels PX may be connected to corresponding signal lines among the above-described signal lines. A connection relationship between the pixels PX and the signal lines may depend on a configuration of a driving circuit of the pixels PX.

The first voltage line PL may receive a first power supply voltage ELVDD. The display panel 100 may receive a second power supply voltage ELVSS. The second power supply voltage ELVSS may have a level lower than that of the first power supply voltage ELVDD.

The second voltage line VL1 may receive a first initialization voltage Vint. The first initialization voltage Vint may have a level lower than that of a first power supply voltage ELVDD. The third voltage line VL2 may receive a second initialization voltage VAint. The second initialization voltage VAint may have a level lower than that of the first power supply voltage ELVDD. At least one of the first initialization voltage Vint and the second initialization voltage VAint may be a bias voltage with a constant level. A level of the first initialization voltage Vint may be different from a level of the second initialization voltage VAint. The second initialization voltage VAint may have a level lower than that of the first initialization voltage Vint.

The pixels PX may include pixel groups that emit light of different colors. For instance, the pixels PX may include red pixels generating a red light, green pixels generating a green light, and blue pixels generating a blue light. A light emitting element of the red pixel, a light emitting element of the green pixel, and a light emitting element of the blue pixel may include light emitting layers containing (and/or formed of) different materials.

FIG. 3B shows the pixel PXij connected to an i-th scan line SLi among the scan lines SL1 to SLn of the first group and connected to a j-th data line DLj among the data lines DL1 to DLm. The pixel PXij may include a pixel driving circuit PC (hereinafter referred to as a pixel circuit PC) and a light emitting element LD.

The pixel circuit PC may include first, second, third, fourth, fifth, sixth, and seventh transistors T1, T2, T3, T4, T5, T6, and T7 and a capacitor Cst. The first transistor T1, the second transistor T2, the fifth transistor T5, the sixth transistor T6, and the seventh transistor T7 may each be a P-type transistor, and the third transistor T3 and the fourth transistor T4 may each be an N-type transistor. Each of the first to seventh transistors T1 to T7 may be a P-type transistor or an N-type transistor.

An input area (or an input electrode) of an N-type transistor may be described as a drain (or a drain area). An input area of a P-type transistor may be described as a source (or a source area). An output area (or an output electrode) of the N-type transistor may be described as a source (or a source area). An output area of the P-type transistor may be described as a drain (or a drain area). At least one of the first to seventh transistors T1 to T7 may be optional.

The first transistor T1, the second transistor T2, the fifth transistor T5, the sixth transistor T6, and the seventh transistor T7 may each be a silicon transistor. The third transistor T3 and the fourth transistor T4 may each be an oxide transistor.

The first transistor T1 may be a driving transistor, and the second transistor T2 may be a switching transistor. The capacitor Cst may be connected between the first voltage line PL (which receives the first power supply voltage ELVDD) and a reference node RN. The capacitor Cst may include a first electrode CE10 electrically connected to the reference node RN and a second electrode CE20 electrically connected to the first voltage line PL.

The first transistor T1 may be electrically connected between the first voltage line PL and one electrode (for example, an anode) of the light emitting element LD. A source S1 of the first transistor T1 may be electrically connected to the first voltage line PL. The expression “a transistor is connected to a signal line” may mean that one of a source electrode, a drain electrode, and a gate electrode of the transistor is provided integrally with the signal line or is electrically connected to the signal line via a connection electrode (and via no intervening transistors). The expression “a first transistor is electrically connected to a second transistor” may mean that one of a source electrode, a drain electrode, and a gate electrode of the first transistor is provided integrally with one of a source electrode, a drain electrode, a gate electrode of the second transistor or is electrically connected to one of the source electrode, the drain electrode, the gate electrode of the second transistor via a connection electrode (and via no intervening transistors). The terms “first” and “second” are used to distinguish two transistors from each other.

A drain D1 of the first transistor T1 may be electrically connected to the anode of the light emitting element LD. The sixth transistor T6 may be optionally disposed between the drain D1 of the first transistor T1 and the anode of the light emitting element LD. A gate G1 of the first transistor T1 may be electrically connected to the reference node RN.

The second transistor T2 may be connected between the j-th data line DLj and the source S1 of the first transistor T1. A source S2 of the second transistor T2 may be electrically connected to the j-th data line DLj, and a drain D2 of the second transistor T2 may be electrically connected to the source S1 of the first transistor T1. A gate G2 of the second transistor T2 may be electrically connected to the i-th scan line SLi of the first group.

The third transistor T3 may be connected between the reference node RN and the drain D1 of the first transistor T1. A drain D3 of the third transistor T3 may be electrically connected to the drain D1 of the first transistor T1, and a source S3 of the third transistor T3 may be electrically connected to the reference node RN. Gates G3-1 and G3-2 of the third transistor T3 may be electrically connected to an i-th scan line GLi of the second group.

The fourth transistor T4 may be electrically connected between the reference node RN and the second voltage line VL1. A drain D4 of the fourth transistor T4 may be electrically connected to the reference node RN, and a source S4 of the fourth transistor T4 may be electrically connected to the second voltage line VL1. Gates G4-1 and G4-2 of the fourth transistor T4 may be electrically connected to an i-th scan line HLi of the third group.

The third and fourth transistors T3 and T4 may each include a plurality of gates. One of the third and fourth transistors T3 and T4 may include a single gate.

The fifth transistor T5 may be electrically connected between the first voltage line PL and the source S1 of the first transistor T1. A source S5 of the fifth transistor T5 may be electrically connected to the first voltage line PL, and a drain D5 of the fifth transistor T5 may be electrically connected to the source S1 of the first transistor T1. A gate G5 of the fifth transistor T5 may be electrically connected to an i-th light emitting line ELi.

The sixth transistor T6 may be connected between the drain D1 of the first transistor T1 and the light emitting element LD. A source S6 of the sixth transistor T6 may be electrically connected to the drain D1 of the first transistor T1, and a drain D6 of the sixth transistor T6 may be electrically connected to the anode of the light emitting element LD. A gate G6 of the sixth transistor T6 may be electrically connected to the i-th light emitting line ELi. The gate G6 of the sixth transistor T6 may be connected to a signal line different from a signal line to which the gate G5 of the fifth transistor T5 is connected.

The seventh transistor T7 may be electrically connected between the drain D6 of the sixth transistor T6 and the third voltage line VL2. A source S7 of the seventh transistor T7 may be electrically connected to the drain D6 of the sixth transistor T6, and a drain D7 of the seventh transistor T7 may be electrically connected to the third voltage line VL2. A gate G7 of the seventh transistor T7 may be electrically connected to an (i+1)th scan line SLi+1 of the first group.

The operation of the pixel PXij is described with reference to FIGS. 3B and 3C. The display device DD may display an image for every frame period. The signal lines of each of the first group of scan lines SL1 to SLn, the second group of scan lines GL1 to GLn, the third group of scan lines HL1 to HLn, and the light emitting lines EL1 to ELn may be sequentially scanned during each frame period. FIG. 3C shows a portion of one frame period.

Referring to FIG. 3C, each of signals EMi, GIi, GCi, and GWi+1 may have a high level V-HIGH for a portion of the period and may have a low level V-LOW for another portion of the period. The N-type transistors may be turned on when a corresponding signal has the high level V-HIGH, and the P-type transistors may be turned on when a corresponding signal has the low level V-LOW.

When a light emitting control signal EMi has the high level V-HIGH, the fifth transistor T5 and the sixth transistor T6 may be turned off. When the fifth transistor T5 and the sixth transistor T6 are turned off, a current path may not be formed between the first voltage line PL and the light emitting element LD. The period during which the fifth transistor T5 and the sixth transistor T6 are turned off may be a non-light-emitting period.

When a scan signal GIi applied to the i-th scan line HLi of the third group has the high level V-HIGH, the fourth transistor T4 may be turned on. When the fourth transistor T4 is turned on, the reference node RN may be initialized by the first initialization voltage Vint. When a scan signal GWi applied to the i-th scan line SLi of the first group has the low level V-LOW and when a scan signal GCi applied to the i-th scan line GLi of the second group has the high level V-HIGH, the second transistor T2 and the third transistor T3 may be turned on.

Since the reference node RN is initialized to the first initialization voltage Vint, the first transistor T1 may be in a turned-on state. When the first transistor T1 is turned on, a voltage corresponding to the data signal Dj (referring to FIG. 3B) may be applied to the reference node RN. As a result, the capacitor Cst may be charged with the voltage corresponding to the data signal Dj. The voltage corresponding to the data signal Dj may be obtained by subtracting a threshold voltage Vth of the first transistor T1 from the data signal Dj.

When a scan signal GWi+1 applied to the (i+1)th scan line SLi+1 of the first group has the low level V-LOW, the seventh transistor T7 may be turned on. As the seventh transistor T7 is turned on, the anode of the light emitting element LD may be initialized to the second initialization voltage VAint. A parasitic capacitance of the light emitting element LD may be discharged.

When the light emitting control signal EMi has the low level V-LOW, the fifth transistor T5 and the sixth transistor T6 may be turned on. When the fifth transistor T5 is turned on, the first power supply voltage ELVDD may be applied to the first transistor T1. When the sixth transistor T6 is turned on, the first transistor T1 and the light emitting element LD may be electrically connected to each other. The light emitting element LD may generate the light having luminance corresponding to the received current.

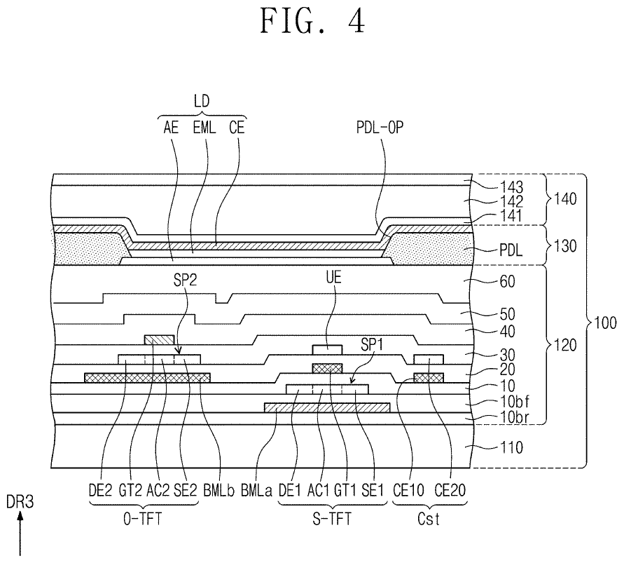

FIG. 4 is a cross-sectional view of the display panel 100 according to an embodiment. FIG. 4 shows a light emitting element LD and shows a silicon transistor S-TFT and an oxide transistor O-TFT of the pixel circuit PC, Referring to FIG. 3B and FIG. 4, the silicon transistor S-TFT may be one of the first transistor T1, the second transistor T2, the fifth transistor T5, the sixth transistor T6, and the seventh transistor T7; the oxide transistor O-TFT may be one of the third and fourth transistors T3 and T4.

A barrier layer 10br may be disposed on the base layer 110. The barrier layer 10br may prevent a foreign substance from affecting the pixel circuit PC. The barrier layer 10br may include at least one inorganic layer. The barrier layer 10br may include a silicon oxide layer and/or a silicon nitride layer. The barrier layer 10br may include silicon oxide layers and silicon nitride layers, which may be alternately stacked.

A first shielding electrode BMLa may be disposed on the barrier layer 10br. The first shielding electrode BMLa may include a metal material. The first shielding electrode BMLa may include molybdenum (Mo), an alloy including molybdenum (Mo), titanium (Ti), or an alloy including titanium (Ti) and may have good heat resistance. The first shielding electrode BMLa may receive a bias voltage. The first shielding electrode BMLa may receive the first power supply voltage ELVDD. The first shielding electrode BMLa may prevent an electric potential caused by a polarization phenomenon from affecting the silicon transistor S-TFT. The first shielding electrode BMLa may prevent an external light from reaching the silicon transistor S-TFT. The first shielding electrode BMLa may be a floating electrode electrically isolated from all other electrodes or lines of the display panel 100.

A buffer layer 10bf may be disposed on the barrier layer 10br. The buffer layer 10bf may prevent metal atoms or impurities from diffusing to a first semiconductor pattern SP1 (disposed on the barrier layer 10br) from the base layer 110. The buffer layer 10bf may include at least one inorganic layer. The buffer layer 10bf may include a silicon oxide layer and a silicon nitride layer.

The first semiconductor pattern SP1 may be disposed on the buffer layer 10bf. The first semiconductor pattern SP1 may include a silicon semiconductor. The silicon semiconductor may include amorphous silicon or polycrystalline silicon. The first semiconductor pattern SP1 may include low temperature polycrystalline silicon.

The first semiconductor pattern SP1 may have different electrical properties depending on whether it is doped or not or doped with an N-type dopant or a P-type dopant. The first semiconductor pattern SP1 may include a high-doped region having a relatively high conductivity and a low-doped region having a relatively low conductivity. The high-doped region may be doped with the N-type dopant or the P-type dopant. A P-type transistor may include a doped region doped with the P-type dopant, and an N-type transistor may include a doped region doped with the N-type dopant. The low-doped region may be a non-doped region or a region doped at a concentration lower than that of the high-doped region.

The high-doped region may substantially serve as an electrode or a signal line. The low-doped region may substantially be a channel area (or an active area) of the transistor. A first portion of the first semiconductor pattern SP1 may be the channel of the transistor, a second portion of the first semiconductor pattern SP1 may be a source or a drain of the transistor, and a third portion of the first semiconductor pattern SP1 may be a connection electrode or a connection signal line.

A source area SE1, a channel area AC1 (or an active area AC1), and a drain area DE1 of the silicon transistor S-TFT may be formed in the first semiconductor pattern SP1. The source area SE1 and the drain area DE1 may be positioned at opposite sides of the channel area AC1 in a cross-section view of the display panel 100.

A first insulating layer 10 may be disposed on the buffer layer 10bf. The first insulating layer 10 may cover the first semiconductor pattern SP1. The first insulating layer 10 may be an inorganic layer. The first insulating layer 10 may include at least one of aluminum oxide, titanium oxide, silicon oxide, silicon nitride, silicon oxynitride, zirconium oxide, and hafnium oxide.

The first insulating layer 10 may have a single-layer structure of a silicon oxide layer. The first insulating layer 10 may have a single-layer or multi-layer structure.

A gate GT1 of the silicon transistor S-TFT may be disposed on the first insulating layer 10. The gate GT1 may be a portion of a metal pattern. The gate GT1 may overlap the channel area AC1. The gate GT1 may be used as a mask in a process of doping the first semiconductor pattern SP1. The gate GT1 may include molybdenum (Mo), an alloy including molybdenum (Mo), titanium (Ti), an alloy including titanium (Ti), or the like and may have good heat resistance.

The first electrode CE10 of the capacitor Cst may be disposed on the first insulating layer 10. In FIG. 4, the gate GT1 and the first electrode CE10 are spaced apart from each other. The first electrode CE10 may extend from the gate GT1 in a plan view of the display panel 100 and may be formed integrally with the gate GT1.

A second shielding electrode BMLb may be disposed on the first insulating layer 10. The second shielding electrode BMLb may be disposed under the oxide transistor O-TFT.

The gate GT1, the first electrode CE10, and the second shielding electrode BMLb may be formed through the same process step, may include the same material, and may have the same stack structure.

A second insulating layer 20 may be disposed on the first insulating layer 10 and may cover the gate GT1, the first electrode CE10, and the second shielding electrode BMLb. The second insulating layer 20 may include at least one of aluminum oxide, titanium oxide, silicon oxide, silicon nitride, silicon oxynitride, zirconium oxide, and hafnium oxide. The second insulating layer 20 may include a plurality of inorganic layers.

A second semiconductor pattern SP2 may be disposed on the second insulating layer 20 and may overlap the second shielding electrode BMLb. The second semiconductor pattern SP2 may include an oxide semiconductor. The second semiconductor pattern SP2 may include a transparent conductive oxide (TCO), such as indium tin oxide (ITO), indium zinc oxide (IZO), indium gallium zinc oxide (IGZO), zinc oxide (ZnOx), or indium oxide (In₂O₃).

The oxide semiconductor may include areas distinguished from each other depending on whether a transparent conductive oxide is reduced. The reduced area in which the transparent conductive oxide is reduced has conductivity greater than that of the non-reduced area in which the transparent conductive oxide is not reduced. The reduced area may substantially act as the source/drain of the transistor or a signal line. The non-reduced area may substantially be the semiconductor area (or the channel) of the transistor. A first portion of the second semiconductor pattern SP2 may be the semiconductor area of the transistor, a second portion of the second semiconductor pattern SP2 may be the source area/drain area of the transistor, and a third portion of the second semiconductor pattern SP2 may be a signal transmission area.

A source area SE2, a channel area AC2 (or an active area AC2), and a drain area DE2 of the oxide transistor O-TFT may be formed in the second semiconductor pattern SP2. The source area SE2 and the drain area DE2 may be positioned at opposite sides of the channel area AC2 in a cross-section view of the display panel 100.

An upper electrode UE may be disposed on the second insulating layer 20 and may overlap the gate GT1. The second electrode CE20 may be disposed on the second insulating layer 20 and may overlap the first electrode CE10. In FIG. 4, the upper electrode UE and the second electrode CE20 are spaced apart from each other. The second electrode CE20 may extend from the upper electrode UE in a plan view of the display panel 100 and may be provided integrally with the upper electrode UE.

The upper electrode UE and the second electrode CE20 may be formed through the same process step as the second semiconductor pattern SP2 and may include the same material as that of the second semiconductor pattern SP2. The upper electrode UE and the second electrode CE20 may have the same stack structure as that of the second semiconductor pattern SP2. The upper electrode UE and the second electrode CE20 may have the same electrical properties as those of the source area SE2 and the drain area DE2 of the oxide transistor O-TFT. The upper electrode UE and the second electrode CE20 may be a reduced area of the transparent conductive oxide similar to the source area SE2 and drain area DE2.

A third insulating layer 30 may be disposed on the second insulating layer 20 and may cover the second semiconductor pattern SP2, the upper electrode UE, and the second electrode CE20. The third insulating layer 30 may have a single-layer structure of an inorganic layer. The third insulating layer 30 may be replaced with an insulating pattern. The insulating pattern may be formed through an etching process using the gate GT1 as a mask and may be aligned with the gate GT1.

A gate GT2 of the oxide transistor O-TFT may be disposed on the third insulating layer 30. The gate GT2 of the oxide transistor O-TFT may be a portion of a metal pattern. The gate GT2 of the oxide transistor O-TFT may overlap the channel area AC2. The gate GT2 may include molybdenum (Mo), an alloy including molybdenum (Mo), titanium (Ti), or an alloy including titanium (Ti) and may have good heat resistance. The gate GT2 may include a titanium layer and a molybdenum layer disposed on the titanium layer.

A fourth insulating layer 40 may be disposed on the third insulating layer 30, and the fourth insulating layer 40 may cover the gate GT2 of the oxide transistor O-TFT. The fourth insulating layer 40 may have a single-layer structure of an inorganic layer.

A fifth insulating layer 50 and a sixth insulating layer 60 may be disposed on the fourth insulating layer 40. Each of the fifth insulating layer 50 and the sixth insulating layer 60 may include an organic layer. The organic layer may include at least one of a general-purpose polymer (such as benzocyclobutene (BCB), polyimide, hexamethyldisiloxane (HMDSO), polymethylmethacrylate (PMMA), or polystyrene (PS)), a polymer derivative having a phenolic group, an acrylic-based polymer, an imide-based polymer, an aryl ether-based polymer, an amide-based polymer, a fluorine-based polymer, a p-xylene-based polymer, and a vinyl alcohol-based polymer.

Although not shown in figures, one or more conductive patterns may be disposed between the fourth insulating layer 40 and the fifth insulating layer 50 and/or between the fifth insulating layer 50 and the sixth insulating layer 60. The conductive pattern(s) may serve as one or more bridges to connect the silicon transistor S-TFT and/or the oxide transistor O-TFT to the light emitting element LD.

The light emitting element LD may include a first electrode AE, a light emitting layer EML, and a second electrode CE (or a common electrode). The first electrode AE of the light emitting element LD may be disposed on the sixth insulating layer 60.

The first electrode AE may be a transmissive electrode, a semi-transmissive electrode, or a reflective electrode. The first electrode AE may include a reflective layer formed of silver (Ag), magnesium (Mg), aluminum (Al), platinum (Pt), lead (Pd), gold (Au), nickel (Ni), Neodymium (Nd), Iridium (Ir), chromium (Cr), and/or a compound/alloy of some of the metals and may include a transparent or semi-transparent electrode layer formed on the reflective layer. The transparent or semi-transparent electrode layer may include at least one of indium tin oxide (ITO), indium zinc oxide (IZO), indium gallium zinc oxide (IGZO), zinc oxide (ZnOx), indium oxide (In₂O₃), and aluminum-doped zinc oxide (AZO). For instance, the first electrode AE may have a stack structure of ITO-Ag-ITO.

A pixel definition layer PDL may be disposed on the sixth insulating layer 60. The pixel definition layer PDL may have a transparent property or a light absorbing property. The pixel definition layer PDL absorbing light and may include a black coloring agent. The black coloring agent may include a black dye or a black pigment. The black coloring agent may include a metal material, such as carbon black, chromium, or an oxide. The pixel definition layer PDL may be a light blocking pattern having a light blocking property.

The pixel definition layer PDL may cover a portion of the first electrode AE. An opening PDL-OP may be defined through the pixel definition layer PDL to expose a portion of the first electrode AE. The pixel definition layer PDL may increase a distance between an edge of the first electrode AE and the second electrode CE, for preventing an arc from occurring in the edge of the first electrode AE.

Although not shown in figures, a hole control layer may be disposed between the first electrode AE and the light emitting layer EML. The hole control layer may include a hole transport layer and may further include a hole injection layer. An electron control layer may be disposed between the light emitting layer EML and the second electrode CE. The electron control layer may include an electron transport layer and may further include an electron injection layer.

The encapsulation layer 140 may be disposed on the light emitting element layer 130. The encapsulation layer 140 may include an inorganic layer 141, an organic layer 142, and an inorganic layer 143, which are sequentially stacked.

The inorganic layers 141 and 143 may protect the light emitting element layer 130 from moisture and oxygen, and the organic layer 142 may protect the light emitting element layer 130 from a foreign substance such as dust particles. The inorganic layers 141 and 143 may include a silicon nitride layer, a silicon oxynitride layer, a silicon oxide layer, a titanium oxide layer, and/or an aluminum oxide layer. The organic layer 142 may include an acrylic-based organic layer.

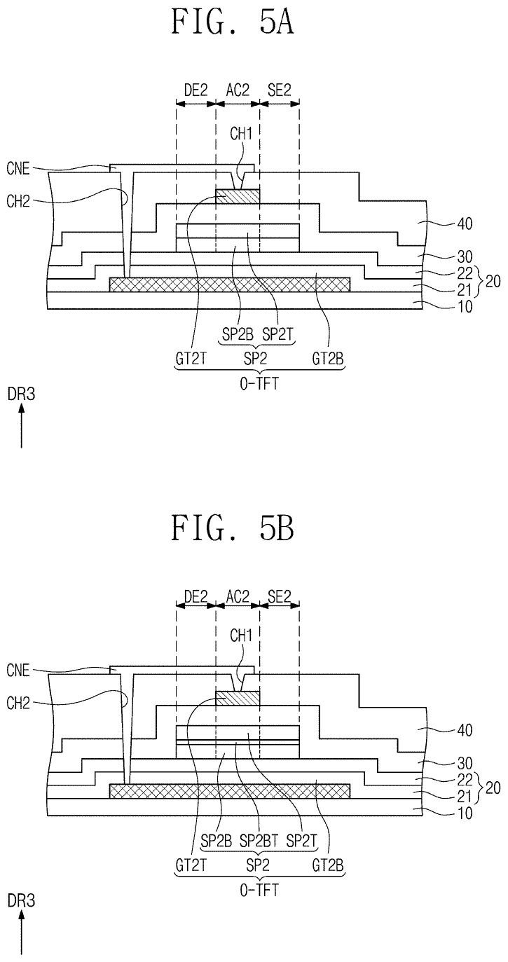

FIG. 5A is a cross-sectional view of the oxide transistor O-TFT according to an embodiment. FIG. 5B is a cross-sectional view of an oxide transistor according to an embodiment.

In FIGS. 5A and 5B, the oxide transistor O-TFT may include a bottom gate GT2B disposed under the second semiconductor pattern SP2 and a top gate GT2T disposed above the second semiconductor pattern SP2. The second semiconductor pattern SP2 may be positioned between the electrodes GT2B and GT2T. The bottom gate GT2B may correspond to the second shielding electrode BMLb shown in FIG. 4, and the top gate GT2T may correspond to the gate GT2 shown in FIG. 4.

The bottom gate GT2B may be electrically connected to the top gate GT2T via a connection electrode CNE. The connection electrode CNE may be connected to the top gate GT2T via a contact hole CH1 formed through the fourth insulating layer 40 and may be connected to the bottom gate GT2B via a contact hole CH2 formed through the insulating layers 20, 30, and 40.

A method of manufacturing the oxide transistor O-TFT is described with reference to FIG. 5A.

The bottom gate GT2B may be formed on the first insulating layer 10. A metal layer may be formed through a deposition process and may be subsequently patterned through a photolithography process and/or an etching process to form the bottom gate GT2B.

Subsequently, at least one second insulating layer 20 may be formed to cover the bottom gate GT2B. A silicon nitride layer 21 and a silicon oxide layer 22 may be sequentially formed through PECVD processes. The PECVD processes may use SiH₄ as a Si precursor. The silicon nitride layer 21 may be formed using NH₃/N₂ as a reactive gas, and the silicon oxide layer 22 may be formed using N₂O as a reactive gas.

In the etching process for forming the bottom gate GT2B, a fluoride gas may be used. After the etching process, fluorinated residues may remain on the first insulating layer 10 or around bottom gate GT2B. The silicon nitride layer 21 may have function as a barrier layer to prevent the fluorinated residues from diffusing to the second semiconductor pattern SP2.

The silicon nitride layer 21 may have a hydrogen concentration higher than that of the silicon oxide layer 22. The silicon nitride layer 21 may have a hydrogen concentration equal to or smaller than 3×10²² at/cm². The silicon oxide layer 22 may have a hydrogen concentration of about 2×10¹⁹ at/cm². Because the silicon oxide layer 22 with the low hydrogen concentration is disposed closer to the second semiconductor pattern SP2 than the silicon nitride layer 21 is, an unwanted change in the conductivity of the second semiconductor pattern SP2 (potentially caused by hydrogen diffusion from the silicon nitride layer 21 toward the second semiconductor pattern SP2) may be minimized.

Subsequently, the second semiconductor pattern SP2 may be formed. The second semiconductor pattern SP2 may include a first area SP2B and a second area SP2T distinguished from the first area SP2B in the third direction DR3. A first oxide semiconductor layer may be formed through a first sputtering process, and subsequently a second oxide semiconductor layer may be formed on the first oxide semiconductor layer through a second sputtering process. The first oxide semiconductor layer and the second oxide semiconductor layer may be patterned through a photolithography process and/or an etching process. The patterned first oxide semiconductor layer may include/be the first area SP2B, and the patterned second oxide semiconductor layer may include/be the second area SP2T.

The first sputtering process and the second sputtering process may be performed under different conditions, e.g., different electric powers (or power intensities) and/or different oxygen partial pressures. Therefore, the first area SP2B and the second area SP2T may have different properties.

An atomic percent (%) of oxygen of the first area SP2B may be lower than an atomic percent (%) of oxygen of the second area SP2T by about 2 atomic percent (%). The first area SP2B may have a relatively low interstitial oxygen concentration. The first area SP2B has a relatively low carrier concentration because the oxygen-oxygen bond is formed less in the first area SP2B. Accordingly, a threshold voltage variation AVth due to a positive bias temperature stress (PBTS) may be low in the first area SP2B.

The second area SP2T may have a relatively high interstitial oxygen concentration compared with the first area SP2B. An unwanted change in a channel property of the channel area AC2, which may be caused by the hydrogen diffusion generated in a process of forming the third insulating layer 30 and a process of forming the fourth insulating layer 40, may be minimized Although a length of the second area SP2T is short, the desirable channel property may be maintained.

In the third direction DR3, the first area SP2B may have a thickness in a range from about 100 angstroms to about 150 angstroms, and the second area SP2T may have a thickness in a range from about 100 angstroms to about 150 angstroms. The maximum thickness of the first area SP2B may be equal to or different from the maximum thickness of the second area SP2T in the third direction DR3.

Referring to FIG. 5B, the second semiconductor pattern SP2 may further include a boundary area SP2BT disposed between the first area SP2B and the second area SP2T, having a higher atomic percent (%) of the oxygen than that of the first area SP2B, and having a lower atomic percent (%) of the oxygen than that of second area SP2T. As the first sputtering process and the second sputtering processes are consecutively carried out, the boundary area SP2BT may be formed. The maximum thickness of the boundary area SP2BT may be smaller than each of the maximum thickness of the first area SP2B and the maximum thickness of the second area SP2T in the third direction DR3.

The upper electrode UE and the second electrode CE20 shown in FIG. 4 may also have the same structure as that of the second semiconductor pattern SP2. The upper electrode UE and the second electrode CE20 may be reduced by the hydrogen diffusion generated in the process of forming the third insulating layer 30 and the process of forming the fourth insulating layer 40 and thus may substantially have desirable conductivity.

The third insulating layer 30 may be formed to cover the second semiconductor pattern SP2. The third insulating layer 30, an inorganic layer, may be formed by a PECVD process and may include a silicon oxide layer. The third insulating layer 30 may have a thickness in a range from about 1000 angstroms to about 1800 angstroms.

The top gate GT2T may be formed on the third insulating layer 30. A metal layer may be formed through a deposition process, and the metal layer may be patterned through a photolithography process and/or an etching process to form the top gate GT2T. The top gate GT2T may be a portion of a corresponding scan line. For instance, the corresponding scan line may be the i-th scan line GLi of the second group or the i-th scan line HLi of the third group shown in FIG. 3B. The scan signal from the i-th scan line GLi of the second group or the i-th scan line HLi of the third group may alternatively or additionally include the bottom gate GT2B. A lower channel and an upper channel may of the second semiconductor pattern SP2 may respectively correspond to the gates GT2B and GT2T.

The fourth insulating layer 40 may be formed to cover the top gate GT2T. The fourth insulating layer 40, an inorganic layer, may be formed through a PECVD process. The fourth insulating layer 40 may include at least a silicon nitride layer. The fourth insulating layer 40 may include a silicon oxide layer and a silicon nitride layer disposed on the silicon oxide layer. In the process of forming the silicon nitride layer, hydrogen may be prevented from significantly diffusing into the channel area AC2 of the second semiconductor pattern SP2 by the top gate GT2T, which may serve as a mask. Accordingly, a channel area AC2 that overlaps the top gate GT2T, a source area SE2 that does not overlap the top gate GT2T, and a drain area DE2 that does not overlap the top gate GT2T may be formed in the second semiconductor pattern SP2. The channel area AC2 may be an area toward which hydrogen diffusion is blocked by the top gate GT2T.

The contact hole CH1 defined through the fourth insulating layer 40 and the contact hole CH2 defined through the second to fourth insulating layer 20 to 40 may be formed by a photolithography process and/or an etching process. Subsequently, the connection electrode CNE may be formed. A metal layer may be formed through a deposition process, and may be substantially patterned through a photolithography process and/or an etching process to form the connection electrode CNE.

The silicon nitride layer 21 and the silicon oxide layer 22 may be partially positioned between the first electrode CE10 and the second electrode CE20 shown in FIG. 4. The silicon oxide layer 22 may have a relatively low dielectric permittivity compared with the silicon nitride layer 21. A thickness of the second insulating layer 20 may be reduced to increase the capacitance of the capacitor Cst. The thickness of the second insulating layer 20 may be within a range from about 1000 angstroms to about 1500 angstroms. In the third direction DR3, a thickness of the silicon nitride layer 21 may be within a range from about 600 angstroms to about 800 angstroms, and a thickness of the silicon oxide layer 22 may be within a range from about 400 angstroms to about 700 angstroms.

When the thickness of the second insulating layer 20 is substantially thin, e.g., in the range from about 1000 angstroms to about 1500 angstroms, a distance between the bottom gate GT2B and the second semiconductor pattern SP2 may be small. Thus, a deterioration of the oxide transistor O-TFT and/or the second semiconductor pattern SP2 may be caused by the bottom gate GT2B if the second semiconductor pattern SP2 does not include the two-layer structure of areas/layers SP2B and SP2T.

Table 1 below shows the threshold voltage variation by positive bias temperature stress (PBTS) depending on the distance between the bottom gate GT2B and the second semiconductor pattern SP2, i.e., the thickness of the second insulating layer 20. The measurement shown in Table 1 is performed on the oxide transistor including the oxide semiconductor having the same structure as that of the second semiconductor pattern SP2 of FIG. 5A but having the single-layer structure different from that of the second semiconductor pattern SP2. The oxide semiconductor having the single-layer structure may have the same property as that of the second area SP2T of FIG. 5A.

TABLE 1

| silicon oxide layer (22)/silicon nitride layer (21) | PBTS ΔVth |
|---|---|
| 3200 Å/900 Å | 0.26 V |
| 500 Å/700 Å | 2.39 V |
| 700 Å/700 Å | 1.32 V |
| 900 Å/700 Å | 0.40 V |

As the distance between the bottom gate GT2B and the second semiconductor pattern SP2 decreases, the threshold voltage variation AVth caused by the positive bias temperature stress (PBTS) increases.

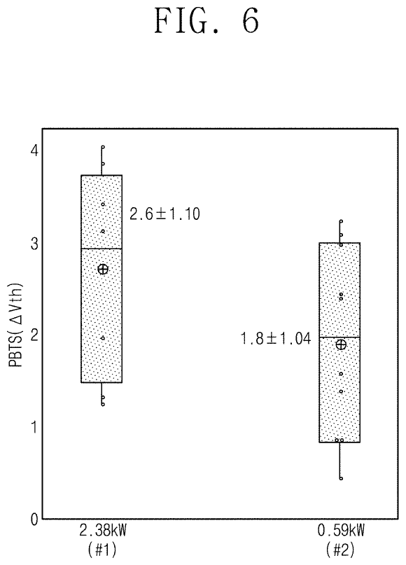

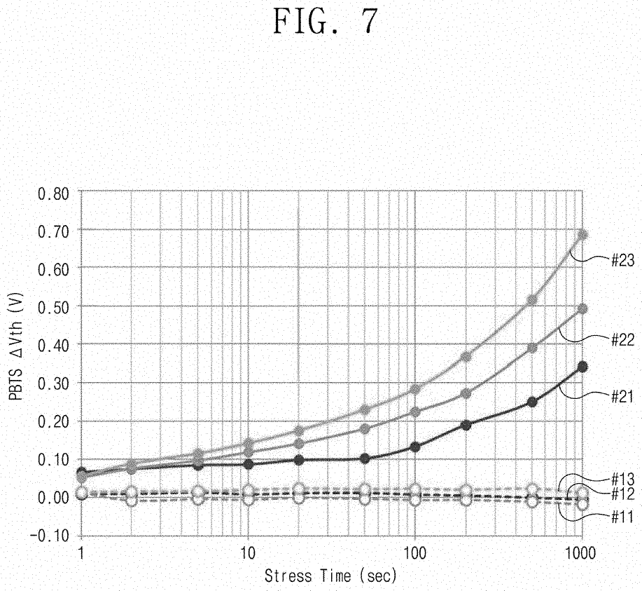

FIG. 6 is a graph of a variation of a threshold voltage as a function of an electric power applied in a sputtering process, and FIG. 7 is a graph of a variation of a threshold voltage as a function of an oxygen partial pressure in a sputtering process.

An oxide transistor including indium gallium zinc oxide (IGZO) is described as an illustrative example.

FIG. 6 shows the threshold voltage variation of the oxide transistor caused by positive bias temperature stress (PBTS) according to a first embodiment (#1) and a second embodiment (#2). Semiconductor patterns according to the first embodiment (#1) and the second embodiment (#2) are formed through a sputtering process with different applied electric powers.

The threshold voltage variation is measured after the oxide transistor having the single-layer structure of indium gallium zinc oxide (IGZO) is manufactured. Initially, the single-layer structure may be different from the second semiconductor pattern SP2 of the oxide transistor O-TFT shown in FIG. 5A.

According to each of the first embodiment (#1) and the second embodiment (#2), the single-layer structure of indium gallium zinc oxide (IGZO) is formed through a sputtering process. The single-layer structure of indium gallium zinc oxide (IGZO) of the second embodiment (#2) is formed by the sputtering process in a state in which a power is applied at a level of about ¼ of a power applied in the single-layer structure of indium gallium zinc oxide (IGZO) of the first embodiment (#1).

In the sputtering process under low power conditions, indium gallium zinc oxide (IGZO) is slowly deposited. Accordingly, a rate of bonding between oxygen and metal is high, and a rate of bonding between oxygen and oxygen is low. Therefore, the interstitial oxygen concentration of the single-layer structure of indium gallium zinc oxide (IGZO) of the second embodiment (#2) is lower than the interstitial oxygen concentration of the single-layer structure of indium gallium zinc oxide (IGZO) of the first embodiment (#1) given the same thickness of the single-layer structure of indium gallium zinc oxide (IGZO). The threshold voltage variation of the second embodiment (#2) is reduced by about 30% when compared with the first embodiment (#1).

Table 2 below represents a composition ratio of indium gallium zinc oxide (IGZO) formed in the sputtering process performed by varying the oxygen partial pressure in the reactive gas. The composition ratio is expressed in atomic percent (%).

TABLE 2

| | Hydrogen | Indium | Gallium | Zinc | Oxygen |
|---|---|---|---|---|---|
| First | 5.11 | 12.61 | 13.87 | 11.66 | 56.75 |
| embodiment | | | | | |
| (#10) | | | | | |
| Second | 3.96 | 12.76 | 14.04 | 11.81 | 57.47 |
| embodiment | | | | | |
| (#20) | | | | | |
| Third | 4.78 | 12.24 | 13.73 | 9.55 | 59.7 |
| embodiment | | | | | |
| (#30) | | | | | |

A mixed gas of argon and oxygen is used as the reactive gas. The oxygen partial pressure in the reactive gas is about 20% in the first embodiment (#10), the oxygen partial pressure in the reactive gas is about 40% in the second embodiment (#20), and the oxygen partial pressure in the reactive gas is about 60% in the third embodiment (#30). As the oxygen partial pressure in the reactive gas increases, the atomic percent (%) of oxygen in indium gallium zinc oxide (IGZO) increases. When the oxygen partial pressure in the reactive gas is controlled during the first sputtering process and the second sputtering process, the second semiconductor pattern SP2 having a two-layer structure shown in FIG. 5A may be formed. For instance, when the oxygen partial pressure is about 20% in the first sputtering process and the oxygen partial pressure is about 60% in the second sputtering process, the first area SP2B having the oxygen concentration lower than that of the second area SP2T by about 2 atomic percent (%) may be formed. When the oxygen partial pressure of the second sputtering process increases higher than about 60%, e.g., about 80%, the second area SP2T having the oxygen concentration higher than about 60 atomic percent (%) may be formed.

FIG. 7 shows the threshold voltage variation caused by positive bias temperature stress (PBTS) of oxide transistors according to a first embodiment (#11) to a sixth embodiment (#23). The oxide transistors according to the first embodiment (#11) to sixth embodiment (#23) may have the same structure as that of the second semiconductor pattern SP2 of the oxide transistor O-TFT shown in FIG. 5A but may have the single-layer structure of indium gallium zinc oxide (IGZO) different from that of the second semiconductor pattern SP2. The threshold voltage variation is measured after the oxide transistors are manufactured according to the first embodiment (#11) to sixth embodiment (#23).

The indium gallium zinc oxide IGZO according to the first embodiment (#11) and the fourth embodiment (#21) is formed under a sputtering process condition in which the oxygen partial pressure in the reactive gas is about 40%, the indium gallium zinc oxide IGZO according to the second embodiment (#12) and the fifth embodiment (#22) is formed under a sputtering process condition in which the oxygen partial pressure in the reactive gas is about 60%, and the indium gallium zinc oxide IGZO according to the third embodiment (#13) and the sixth embodiment (#23) is formed under a sputtering process condition in which the oxygen partial pressure in the reactive gas is about 80%.

According to the first embodiment (#11) to the third embodiment (#13), a turn-on voltage of about 20 V is applied to the top gate GT2T, and a ground voltage is applied to the bottom gate GT2B. According to the fourth embodiment (#21) to the sixth embodiment (#23), the ground voltage is applied to the top gate GT2T, and the turn-on voltage of about 20 V is applied to the bottom gate GT2B.

Referring to FIG. 7, it is observed that the threshold voltage variation of the oxide transistor is sensitive to the deterioration of the bottom gate GT2B. As described with reference to FIG. 5A, this is because the thickness of the second insulating layer 20 is relatively smaller than the thickness of the third insulating layer 30.

According to the first embodiment (#11), the second embodiment (#2), and the third embodiment (#13) and according to the fourth embodiment (#21), the fifth embodiment (#5), and the sixth embodiment (#23), the threshold voltage variation increases as the oxygen partial pressure in the reactive gas used in the sputtering process becomes higher.

This is because, as shown in Table 2, when the oxygen partial pressure in the reactive gas used in the sputtering process is high, the atomic percent (%) of oxygen in indium gallium zinc oxide IGZO increases. For the same reason related to the differences between the first area SP2B and the second area SP2T described with reference to FIG. 5A, when the atomic percent (%) of oxygen in indium gallium zinc oxide IGZO is large, the threshold voltage variation increases.

Referring to FIG. 5A, since the first area SP2B disposed closer to the bottom gate GT2B has the atomic percent (%) of oxygen lower than that of the second area SP2T, the first area SP2B may be relatively insensitive to the influence by the bottom gate GT2B.

The second area SP2T adjacent to the top gate GT2T is placed relatively far from the bottom gate GT2B; thus, the second area SP2T receives relatively little stress. Since the second area SP2T adjacent to the top gate GT2T has a relatively high atomic percent (%) of oxygen, the channel property may be maintained constant, and an unwanted process variance (the difference in the threshold voltage variation of the transistor depending on the pixels) may be minimized.

Although examples of embodiments have been described, practical embodiments should not be limited to the described embodiments. Various changes and modifications can be made to the described embodiments within the scope of the claims.

What is claimed is:

1. A display panel comprising:
a light emitting element; and
a pixel circuit electrically connected to the light emitting element, the pixel circuit comprising a first transistor, the first transistor comprising:
a first gate;
an oxide semiconductor member overlapping the first gate;
a second gate overlapping the oxide semiconductor member;
a first insulating layer disposed between the first gate and the oxide semiconductor member; and
a second insulating layer disposed between the oxide semiconductor member and the second gate, wherein the oxide semiconductor member is disposed between the first gate and the second gate and comprises:
a first semiconductor layer; and
a second semiconductor layer disposed between the first semiconductor layer and the second gate in a thickness direction of the oxide semiconductor member, wherein an atomic percent of oxygen of the first semiconductor layer is lower than an atomic percent of oxygen of the second semiconductor layer.

2. The display panel of claim 1, wherein a thickness of the first semiconductor layer is in a range of 100 angstroms to 150 angstroms, and wherein a thickness of the second semiconductor layer is in a range of 100 angstroms to 150 angstroms.

3. The display panel of claim 1, wherein the oxide semiconductor member further comprises a boundary semiconductor layer disposed between the first semiconductor layer and the second semiconductor layer, wherein an atomic percent of oxygen of the boundary semiconductor layer is higher than the atomic percent of oxygen of the first semiconductor layer and is lower than the atomic percent of oxygen of the second semiconductor layer, and wherein a maximum thickness of the boundary semiconductor layer is less than each of a maximum thickness of the first semiconductor layer and a maximum thickness of the second semiconductor layer in the thickness direction of the oxide semiconductor member.

4. The display panel of claim 1, wherein the atomic percent of oxygen of the first semiconductor layer is lower than the atomic percent of oxygen of the second semiconductor layer by at least 2 atomic percent.

5. The display panel of claim 1, wherein the oxide semiconductor member comprises an indium gallium zinc oxide, and wherein the atomic percent of oxygen of the first semiconductor layer is in a range from 40 atomic percent to 60 atomic percent.

6. The display panel of claim 1, wherein the pixel circuit further comprises a capacitor, and wherein the capacitor comprises:
a first electrode disposed on the first insulating layer and comprising a same transparent conductive oxide as the oxide semiconductor member; and
a second electrode, wherein the first electrode and the second electrode overlap each other.

7. The display panel of claim 6, wherein the first insulating layer is partially disposed between the first electrode and the second electrode.

8. The display panel of claim 7, wherein the first insulating layer comprises a silicon oxide layer and a silicon nitride layer disposed on the silicon oxide layer, and wherein a thickness of the first insulating layer is in a range from 1000 angstroms to 1500 angstroms.

9. The display panel of claim 1, wherein a maximum thickness of the first insulating layer is less than a maximum thickness of the second insulating layer in the thickness direction of the oxide semiconductor member.

10. The display panel of claim 1, wherein the pixel circuit further comprises a second transistor and an overlapping electrode, wherein the second transistor comprises:
a silicon semiconductor member; and
a gate electrode overlapping the silicon semiconductor member and disposed between the overlapping electrode and the silicon semiconductor member, and
wherein the overlapping electrode overlaps the gate electrode, is disposed on the first insulating layer, and comprises a same transparent conductive oxide as the oxide semiconductor member.

11. The display panel of claim 10, wherein the first insulating layer is partially disposed between the gate electrode and the overlapping electrode.

12. The display panel of claim 10, wherein the first gate of the first transistor and the gate electrode of the second transistor comprise a same material.

13. The display panel of claim 1, further comprising:
a third insulating layer covering the second gate; and
a connection electrode disposed on the third insulating layer and electrically connecting the second gate and the first gate.

14. The display panel of claim 13, wherein the connection electrode is connected to the second gate via a first contact hole through the third insulating layer and is connected to the first gate via a second contact hole through the first insulating layer, the second insulating layer, and the third insulating layer.

15. The display panel of claim 1, wherein the second semiconductor layer comprises a channel, a drain, and a source, and wherein the channel is overlapped by the second gate and is positioned between the drain and the source.

16. A method of manufacturing a display panel, the method comprising:
forming a first gate of a first transistor:
forming a first insulating layer on the first gate;
forming an oxide semiconductor member of the first transistor on the first insulating layer;
forming a second insulating layer on the oxide semiconductor member; and
forming a second gate of the first transistor on the second insulating layer, wherein the forming of the oxide semiconductor member comprises:
forming a first semiconductor layer by performing at least a first sputtering process; and
forming a second semiconductor layer on the first semiconductor layer by performing at least a second sputtering process, wherein the first sputtering process and the second sputtering process are performed according to at least one of a first condition and a second condition, wherein a power for performing the first sputtering process is lower than a power for performing the second sputtering process according to the first condition, wherein an oxygen partial pressure in a reactive gas used in the first sputtering process is lower than an oxygen partial pressure in a reactive gas used in the second sputtering process according to the second condition, and wherein the second semiconductor layer is positioned between the first semiconductor layer and the second gate in the display panel.

17. The method of claim 16, further comprising forming a connection electrode that electrically connects the second gate and the first gate.

18. The method of claim 16, wherein the oxygen partial pressure in the reactive gas of the first sputtering process is in a range from 10% to 60%.

19. The method of claim 16, further comprising forming a silicon semiconductor member of a second transistor before the forming of the first gate, wherein a gate of the second transistor is formed during the forming of the first gate, and wherein the gate of the second transistor is spaced from the first gate and overlaps the silicon semiconductor member.

20. The method of claim 19, further comprising forming an overlapping electrode during the forming of the oxide semiconductor member, wherein the overlapping electrode is spaced from the oxide semiconductor member and overlaps the gate of the second transistor.
